(19) United States
(12) Patent Application Publication
(10) Pub. No.: US 2013/0111294 A1
(43) Pub. Date: May 2, 2013

(54) Systems and Methods for Late Stage Precoding

(71) Applicants: Weijun Tan, Longrnont, CO (US); Shaohua Yang, San Jose, CA (US); Zongwang Li, San Jose, CA (US); Victor Krachkovsky, Allentown, PA (US)

(72) Inventors: Weijun Tan, Longrnont, CO (US); Shaohua Yang, San Jose, CA (US); Zongwang Li, San Jose, CA (US); Victor Krachkovsky, Allentown, PA (US)

(73) Assignee: LSI Corporation

(21) Appl. No.: 13/284,819

(22) Filed: Oct. 28, 2011

(51) Int. Cl. H03M 13/29; G06F 11/10

(52) U.S. Cl. 714/755; 714/E11.032

(57) ABSTRACT

Various embodiments of the present invention provide systems, devices and methods for data processing. As an example, a data processing device is discussed that include a data encoding system and a data decoding system. The data encoding system is operable to receive a data input, and to: apply a maximum transition run length encoding to the data input to yield a run length limited output; apply a low density parity check encoding algorithm to the run length limited output to yield a number of original parity bits; apply a precode algorithm to the original parity bits to yield precoded parity bits; and combine the precoded parity bits and a derivative of the run length limited output to yield an output data set.

### BACKGROUND OF THE INVENTION

The present invention is related to systems and methods for processing data, and more particularly to systems and methods for performing a data detection.

The capacity and/or bandwidth of storage devices and data transfer devices continues to increase. Such an increase has led to a need for more powerful signal processing techniques. In some cases, maximum transition run length encoding has been added to processing channels. In other cases, precoding has been applied to a channel. As precoding and maximum transition run length encoding conflict with each other, data processing circuits have employed one or the other, but not both. Such a requirement to select one advantageous processing mode or another often leaves a processing circuit under powered.

Hence, for at least the aforementioned reasons, there exists a need in the art for advanced systems and methods for data processing.

### BRIEF SUMMARY OF THE INVENTION

The present invention is related to systems and methods for processing data, and more particularly to systems and methods for performing a data detection.

Various embodiments of the present invention provide data processing devices. Such data processing devices may be, but are not limited to, data storage device, wireless communication devices or wired communication devices. The data processing devices include a data encoding system and a data decoding system. The data encoding system is operable to receive a data input, and to: apply a maximum transition run length encoding to the data input to yield a run length limited output; apply a low density parity check encoding algorithm to the run length limited output to yield a number of original parity bits; apply a precode algorithm to the original parity bits to yield precoded parity bits; and combine the precoded parity bits and a derivative of the run length limited output to yield an output data set. The data decoding system is operable to receive the output data set, and to: perform a data detection on the output data set to yield a detected output; and apply a low density parity check decode algorithm to a derivative of the detected output to yield a decoded output. In some cases, the data encoding system is implemented as part of one integrated circuit, and the data decoding system is implemented as part of another integrated circuit. In various cases, the data encoding system and the data decoding system are implemented as part of an integrated circuit.

In some instances of the aforementioned embodiments, performing the data detection includes applying a data detection algorithm that may be, but is not limited to, a maximum a posteriori data detection algorithm, or a Viterbi data detection algorithm. In various instances of the aforementioned embodiments, the derivative of the run length limited output is the run length limited output. In such instances, performing the data detection includes: applying a precode decoding algorithm to at least the precoded parity bits to yield the original parity bits; and applying a data detection algorithm to a combination of the original parity bits and the run length limited output to yield the detected output. In other instances of the aforementioned embodiments, the precode algorithm is a first precode algorithm, and the data encoding system is further operable to apply a second precode algorithm to the run length limited output to yield the derivative of the run length limited output. In such instances, performing the data detection includes applying a combination data detection algorithm and precode decoding algorithm to the output data set to yield the detected output.

Other embodiments of the present invention provide data processing systems that include a data encoding system operable to receive a data input, and to: apply a maximum transition run length encoding to the data input to yield a run length limited output; apply an encoding algorithm to the run length limited output to yield a number of original parity bits; apply a precode algorithm to the original parity bits to yield precoded parity bits; and combine the precoded parity bits and a derivative of the run length limited output to yield an output data set. In some cases, the derivative of the run length limited output is the run length limited output. In other cases, the precode algorithm is a first precode algorithm, and the data encoding system is further operable to apply a second precode algorithm to the run length limited output to yield the derivative of the run length limited output. In some such cases, applying the precode algorithm to the original parity bits to yield the precoded parity bits includes replacing portions of the original parity bits with replacement parity bits. In one or more cases, the data processing system further includes a look up table operable to store the replacement parity bits. In such cases, the look up table is addressed by respective derivatives of the portions of the original parity bits to yield the corresponding replacement parity bits. In particular instances of the aforementioned embodiments, the encoding algorithm is a low density parity check encoding algorithm.

Yet other embodiments of the present invention provide data processing systems that include a data decoding system operable to receive an output data set. The output data set includes a combination of a derivative of a run length limited output and precoded parity bits. The data decoding system is further operable to: perform a data detection on the output data set to yield a detected output; and apply a parity check based decode algorithm to the detected output to yield a decoded output. In some cases, the parity check based decode algorithm is a low density parity check decoding algorithm. In various instances of the aforementioned embodiments, performing the data detection includes applying a data detection algorithm that may be, but is not limited to, a maximum a posteriori data detection algorithm, or a Viterbi data detection algorithm. In one or more instances of the aforementioned embodiments, the derivative of the run length limited output is the run length limited output. In such instances, the data detection may include: applying a precode decoding algorithm to at least the precoded parity bits to yield the original parity bits; and applying a data detection algorithm to a combination of the original parity bits and the run length limited output to yield the detected output. In some such instances, applying the precode decoding algorithm to at least the precoded parity bits to yield the original parity bits includes replacing portions of the precoded parity bits with replacement parity bits. In some cases, the data processing system further includes a look up table operable to store the replacement parity bits. In such cases, the look up table is addressed by respective derivatives of the portions of the precoded parity bits to yield the corresponding replacement parity bits. In other instances of the aforementioned embodiments, the derivative of the run length limited output is a precoded version of the run length limited output. In such instances, performing the data detection includes applying a combination data detection algorithm and precode decoding algorithm to the output data set to yield the detected output.

This summary provides only a general outline of some embodiments of the invention. Many other objects, features, advantages and other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a data encoder circuit in accordance with some embodiments of the present invention;

FIGS. 2a-2d provide examples of the output of the stages of the data encoder circuit of FIG. 1;

FIG. 3 is a flow diagram showing a method in accordance with some embodiments of the present invention for performing a combination of maximum transmission run length encoding and generalized precoding in accordance with one or more embodiments of the present invention;

FIG. 4 shows a data encoder circuit in accordance with some embodiments of the present invention;

FIGS. 5a-5d provide examples of the output of the stages of the data encoder circuit of FIG. 4;

FIG. 6 is a flow diagram showing a method in accordance with other embodiments of the present invention for performing a combination of maximum transmission run length encoding and generalized precoding in accordance with one or more embodiments of the present invention;

FIG. 7a depicts a data processing circuit that includes a data detector circuit having a reverse generalized precoding in accordance with some embodiments of the present invention;

FIG. 7b depicts one implementation of a data detector circuit including a reverse generalized precoding circuit that may be used in relation to the data processing circuit of FIG. 7a in accordance with some embodiments of the present invention;

FIG. 8 is a flow diagram showing a method in accordance with some embodiments of the present invention for data detection that includes a reverse generalized precoding in accordance with some embodiments of the present invention;

FIG. 9 depicts a storage device including late stage precoding data preparation circuitry and corresponding data detection circuitry is shown in accordance with one or more embodiments of the present invention; and

FIG. 10 shows a communication system including a transceiver having late stage precoding data preparation circuitry and corresponding data detection circuitry in accordance with one or more embodiments of the present invention.

### DETAILED DESCRIPTION OF THE INVENTION

The present invention is related to systems and methods for processing data, and more particularly to systems and methods for performing a data detection.

Various embodiments of the present invention provide data detection circuits and/or data detection methods that achieve a combination of the benefits of maximum transition run length encoding and generalized precoding at the same time. In some cases, this benefit is achieved by performing maximum transition run length encoding to yield an MTR output, and a low density parity check encoding is performed to calculate parity bits to be added to the MTR output to yield a decoded output. A first generalized precoding is applied to the MTR output that includes only user data to yield a first precoded output, and a second generalized precoding is applied to the decoded output including the parity bits to yield a second precoded output. The first precoded output and the second precoded output are combined to yield an output data set.

A data detection algorithm is applied to the output data set by a data detector circuit. The data detector circuit provides a detected output that corresponds to the non-precoded user bits and to the precoded parity bits. In some cases, a look up table including generalized precoding mapping information is used in real time that allows processing of non-precoded user bits and precoded parity bits at given time.

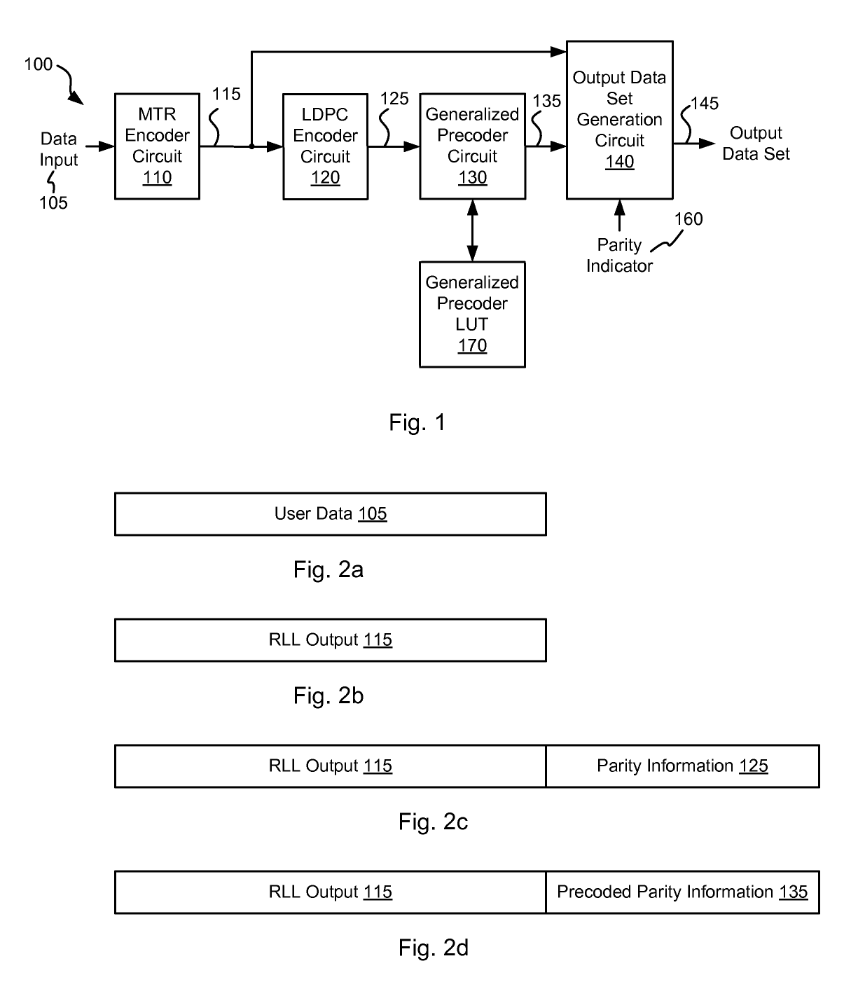

Turning to FIG. 1, a data encoder circuit 100 is shown in accordance with some embodiments of the present invention. Data encoder circuit 100 includes a maximum transmission run length encoder circuit 110 that is operable to receive a data input 105. Data input 105 is a set of user data that are intended to be stored to a storage medium or transferred via a transmission medium. Maximum transmission run length encoder circuit 110 is operable to modify the received data stream to limit the number of consecutive transitions that occur one after another. The output stream is commonly referred to as NRZI data whereas data input 105 is commonly referred to as NRZ data. In some embodiments of the present invention, the number of consecutive transitioning bits is three. In some cases, maximum transmission run length encoder circuit 110 operates in accordance with Cideciyan, Roy D. et al., “Maximum Transition Run Codes for Generalized Partial Response Channels”, IEEE Journal in Selected Areas in Communications, Vol. 19, No. 4, April 2001. The entirety of the aforementioned article is incorporated herein by reference for all purposes. Maximum transmission run length encoder circuit 110 provides a run length limited output 115 to a low density parity check encoder circuit 120, and to an output data set generation circuit 140.

Low density parity check encoder circuit 120 calculates parity information to be included with run length limited output 115 to yield a valid low density parity check codeword. The calculated parity information is provided as a parity output 125 to a generalized precoder circuit 130. Generalized precoder circuit 130 provides sequential portions of parity information 125 to a generalized precoder look up table 170. Generalized precoder look up table 170 provides replacement data in place of the presented portion of parity information 125. The replacement data is provided as precoded parity information 135. The replacement data is comprised of patterns that yield better bit rate error performance. In some embodiments of the present invention, the replaced portions of parity information 125 are four bit portions that are replaced with corresponding four bit portions. Precoded parity information 135 is incorporated with run length limited output 115 by an output data set generation circuit 140 based upon a parity indicator 160 that identifies which bits of run length limited output 115 are associated with precoded parity information 135. The combined run length limited output 115 and precoded parity information 135 is provided as an output data set 145. In turn, output data set 145 is prepared and provided to a storage medium and/or data transfer medium.

FIGS. 2a-2d provide examples of the output of the stages of data encoder circuit 100. In particular, FIG. 2a shows user data 105 that is provided to maximum transmission run length encoder circuit 110, and FIG. 2b shows user data 105 after encoding to yield run length limited output 115. FIG. 2c shows run length limited output 115 along with parity information 125 generated as part of the low density parity check encoding process. FIG. 2d shows output data set 145 including the combination of run length limited output 115 and precoded parity information 135.

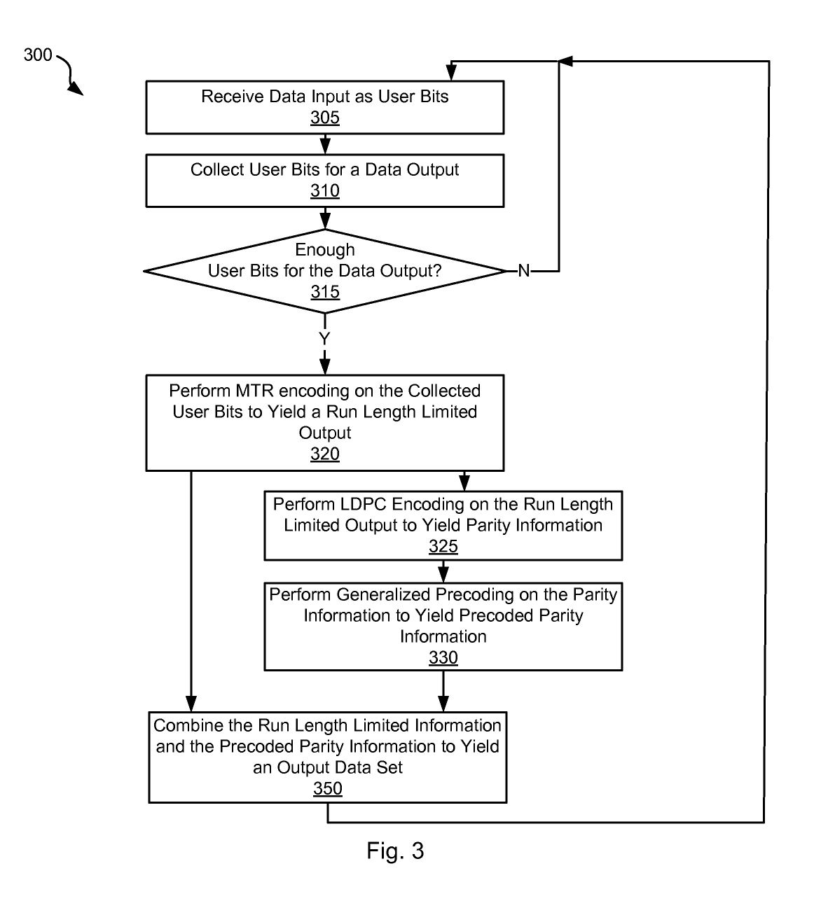

Turning to FIG. 3, a flow diagram 300 shows a method in accordance with some embodiments of the present invention for performing a combination of maximum transmission run length encoding and generalized precoding in accordance with one or more embodiments of the present invention. Following flow diagram 300, a data input is received as a number of user data bits (block 305). A Number of the user data bits are collected (block 310) until it is determined that a sufficient number of user data bits to create a data output have been received (block 315). Where enough user data bits have been collected (block 315), maximum transition run encoding is applied to the collected user data to yield a run length limited output (block 320). Low density parity check encoding is applied to the run length limited output to yield parity information (block 325), and the generalized precoding is applied to the parity information to yield precoded parity information (block 330). The run length limited output is combined with the precoded parity information to yield an output data set (block 350).

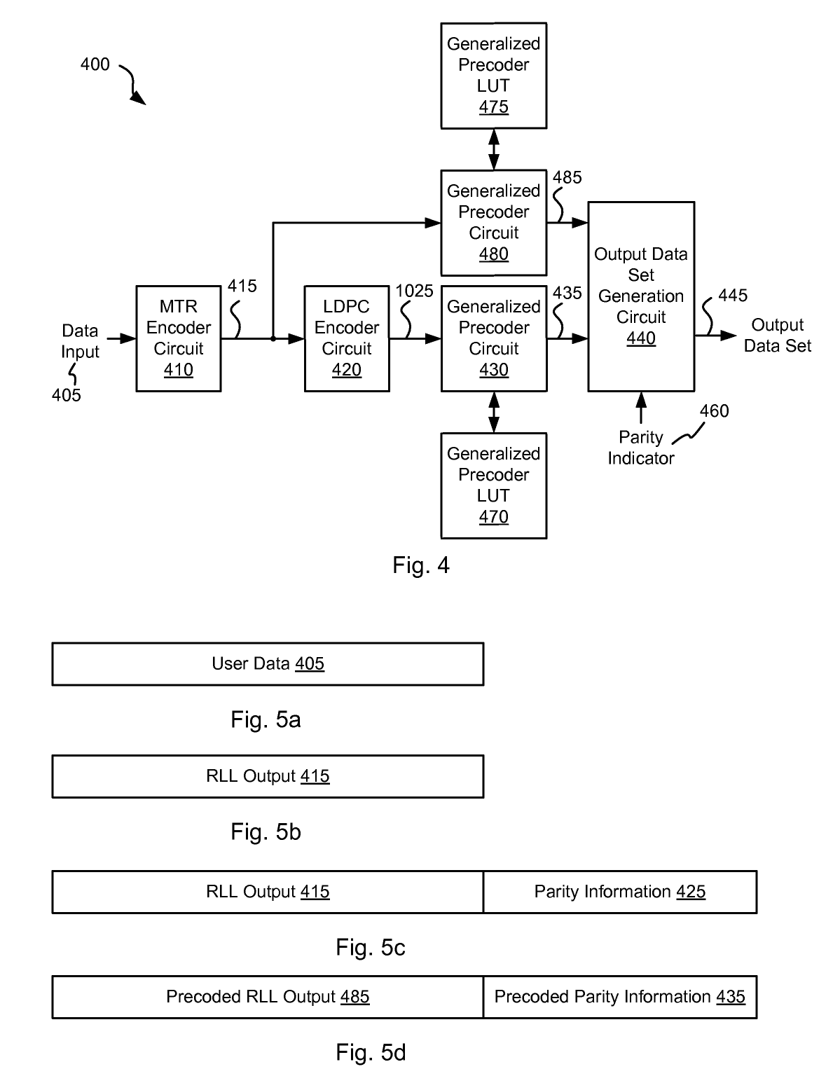

Turning to FIG. 4, a data encoder circuit 400 is shown in accordance with some embodiments of the present invention. Data encoder circuit 400 includes a maximum transmission run length encoder circuit 410 that is operable to receive a data input 405. Data input 405 is a set of user data that are intended to be stored to a storage medium or transferred via a transmission medium. Maximum transition run length encoder circuit 410 is operable to modify the received data stream to limit the number of consecutive transitions in a row. In the output stream is commonly referred to as NRZI data whereas data input 405 is commonly referred to as NRZ data. In some embodiments of the present invention, the number of consecutive non-transitioning bits is three. In some cases, maximum transmission run length encoder circuit 710 operates in accordance with Cideciyan, Roy D. et al., “Maximum Transition Run Codes for Generalized Partial Response Channels”, IEEE Journal in Selected Areas in Communications, Vol. 19, No. 4, April 2001. The entirety of the aforementioned article is incorporated herein by reference for all purposes. Maximum transmission run length encoder circuit 410 provides a run length limited output 415 to a low density parity check encoder circuit 420, and to a generalized precoder circuit 480.

Generalized precoder circuit 480 provides sequential portions of run length limited output 415 to a generalized precoder look up table 475. Generalized precoder look up table 475 provides replacement data in place of the presented portion of run length limited output 415. The replacement data is provided as precoded run length limited output 485. The replacement data is comprised of patterns that yield better bit rate error performance. The replacement portions provided from generalized look up table 475 are selected to avoid consecutive number of non-transitional data consistent with the limits enforced by maximum transmission run length encoder circuit 410 such that it does not undo the advantages created by the run length limited encoding.

Low density parity check encoder circuit 420 calculates parity information to be included with run length limited output 415 to yield a valid low density parity check codeword. The calculated parity information is provided as a parity output 425 to a generalized precoder circuit 430. Generalized precoder circuit 430 provides sequential portions of parity information 425 to a generalized precoder look up table 470. Generalized precoder look up table 470 provides replacement data in place of the presented portion of parity information 425. The replacement data is provided as precoded parity information 435. The replacement data is comprised of patterns that yield better bit rate error performance. Precoded parity information 435 is incorporated with run length limited output 415 by an output data set generation circuit 440 based upon a parity indicator 460 that identifies which bits of run length limited output 415 (formed into precoded run length limited output 485) are associated with precoded parity information 435. The combined precoded run length limited output 485 and precoded parity information 435 is provided as an output data set 445. In turn, output data set 445 is prepared and provided to a storage medium and/or data transfer medium.

FIGS. 5a-5d provide examples of the output of the stages of data encoder circuit 400. In particular, FIG. 5a shows user data 405 that is provided to maximum transmission run length encoder circuit 410, and FIG. 5b shows user data 405 after encoding to yield run length limited output 415. FIG. 5c shows run length limited output 415 along with parity information 425 generated as part of the low density parity check encoding process. FIG. 5d shows output data set 445 including the combination of precoded run length limited output 415 and precoded parity information 435.

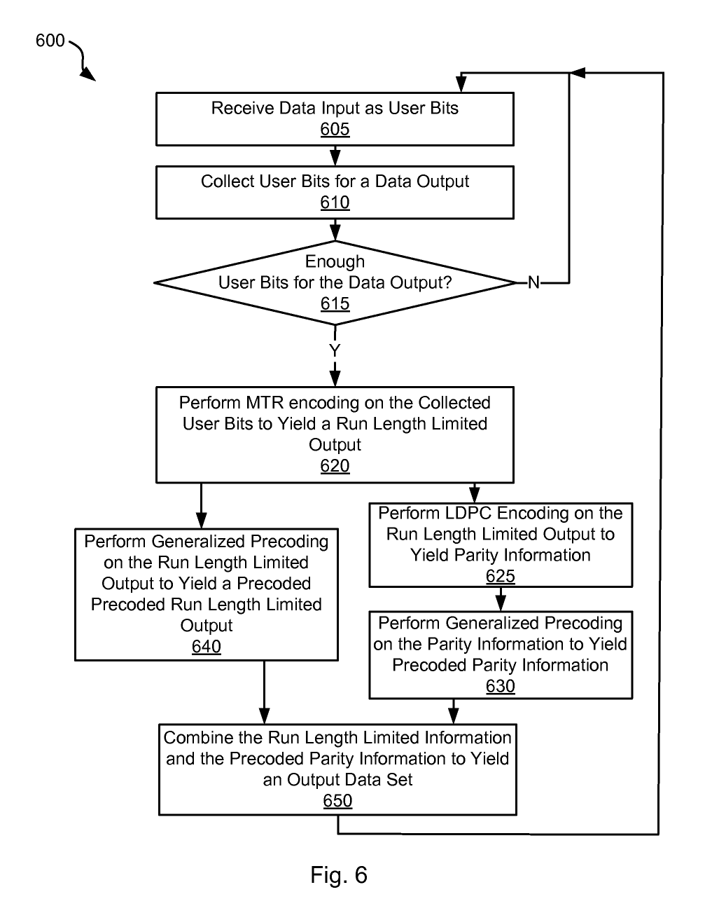

Turning to FIG. 6, a flow diagram 600 shows a method in accordance with other embodiments of the present invention for performing a combination of maximum transmission run length encoding and generalized precoding in accordance with one or more embodiments of the present invention. Following flow diagram 600, a data input is received as a number of user data bits (block 605). A Number of the user data bits are collected (block 610) until it is determined that a sufficient number of user data bits to create a data output have been received (block 615). Where enough user data bits have been collected (block 615), maximum transition run encoding is applied to the collected user data to yield a run length limited output (block 620). Low density parity check encoding is applied to the run length limited output to yield parity information (block 625), and the generalized precoding is applied to the parity information to yield precoded parity information (block 630). In parallel, generalized precoding is applied to the run length limited output to yield a precoded run length limited output parity information (block 640). The generalized precoding applied to the run length limited output (block 640) uses different replacement values than the generalized precoding applied to the parity information (block 630). The precoded run length limited output is combined with the precoded parity information to yield an output data set (block 650).

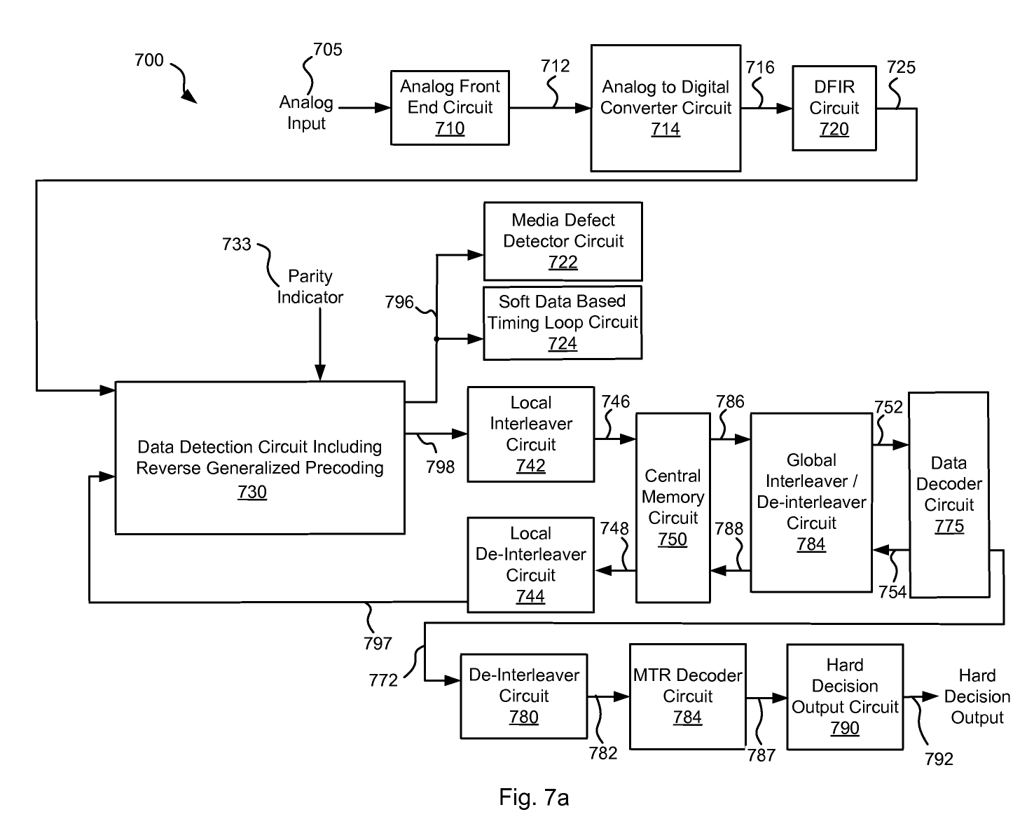

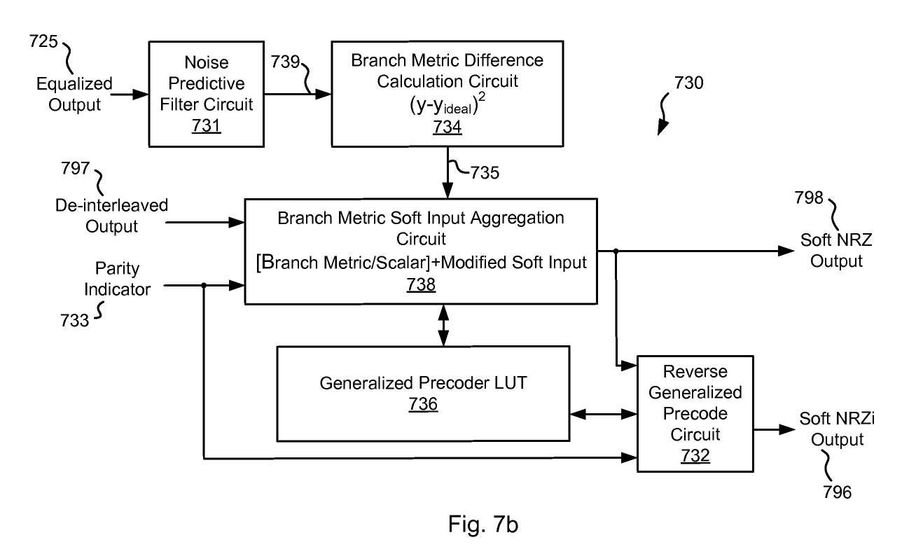

Turning to FIG. 7, a data processing circuit 700 is shown that includes a data detector circuit 730 that includes reverse generalized precoding in accordance with some embodiments of the present invention. Data processing circuit 700 includes an analog front end circuit 710. Analog front end circuit 710 may include, but is not limited to, an analog filter and an amplifier circuit as are known in the art. Based upon the disclosure provided herein, one of ordinary skill in the art will recognize a variety of circuitry that may be included as part of analog front end circuit 710. In some cases, the gain of a variable gain amplifier included as part of analog front circuit 710 may be modifiable, and the cutoff frequency and boost of an analog filter included in analog front end circuit 710 may be modifiable. Analog front end circuit 710 receives and processes an analog signal 705, and provides a processed analog signal 712 to an analog to digital converter circuit 714. In some cases, analog signal 705 is derived from a read/write head assembly (not shown) that is disposed in relation to a storage medium (not shown). In other cases, analog signal 705 is derived from a receiver circuit (not shown) that is operable to receive a signal from a transmission medium (not shown). The transmission medium may be wireless or wired such as, but not limited to, cable or optical connectivity. Based upon the disclosure provided herein, one of ordinary skill in the art will recognize a variety of sources from which analog input 705 may be derived.

Analog to digital converter circuit 714 converts processed analog signal 712 into a corresponding series of digital samples 716. Analog to digital converter circuit 714 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 716 are provided to an equalizer circuit 720. Equalizer circuit 720 applies an equalization algorithm to digital samples 716 to yield an equalized output 725. In some embodiments of the present invention, equalizer circuit 720 is a digital finite impulse response filter circuit as are known in the art. Equalized output 725 is provided to a data detector circuit 730. In some cases, equalizer 720 includes sufficient memory to maintain one or more codewords until a data detector circuit 730 is available for processing. As an example, equalized output 725 may be similar to the data set shown in FIG. 2d including a run length limited output and precoded parity information. A parity indicator 733 is asserted as a logic ‘1’ when precoded parity information is being received and is a logic ‘0’ when run length limited output is being received. Parity indicator 733 may be provided from a counter circuit (not shown) that monitors the received data set input.

Data detector circuit 730 includes reverse generalized precoding and receives equalized output 725, parity indicator 733, and a de-interleaved output 797. When parity indicator 733 is asserted high it indicates that parity information is being received as part of equalized output 725, and when parity indicator 733 is asserted low it indicates that user information is being received as part of equalized output 725. Data detector circuit 730 operates one way when parity indicator 733 is asserted high and another way when parity indicator 733 is asserted low. The difference in operation accounts for the different manner that parity information is encoded as opposed to the user information. This difference in encoding is described, for example, in relation to FIG. 4 above. Data detector circuit 730 provides a soft NRZ output 796 to a media defect detector circuit 722 and a soft data based timing loop circuit 724, and a soft NRZi output 798 to a local interleaver circuit 742.

Turning to FIG. 7b, one implementation of a data detector circuit 730 including a reverse generalized precoding circuit is shown that may be used in relation to the data processing circuit of FIG. 7a in accordance with some embodiments of the present invention. Data detector circuit 730 includes a noise predictive filter circuit 731 that filters equalized output 725 and provides a corresponding noise filtered output 739 to a branch metric difference calculation circuit 734. Noise predictive filter circuit 731 may be any circuit known in the art that is capable of performing noise predictive filtering on a received input. Based upon the disclosure provided herein, one of ordinary skill in the art will recognize a variety of noise predictive filter circuits that may be used in relation to different embodiments of the present invention.

Branch metric difference calculation circuit 734 performs a standard branch metric calculation based upon the received input in accordance with the following equation:

Branch Metric=(y−Y_{ideal})²,

where y is the received input, and y_{ideal} is an expected value of the received input. The calculated branch metrics for the received noise filtered outputs 739 are provided as branch outputs 735 to a branch metric soft input aggregation circuit 738. Branch metric soft input aggregation circuit 738 performs a calculation that is dependent upon parity indicator 733. In particular, branch metric soft input aggregation circuit 738 is operable to perform the following calculation:

Output=[Branch Metric/Scalar 1]+Modified Soft Input,

where Scalar 1 is a user programmable value, Branch Metric is received as branch metric outputs 735, and Modified Soft Input is calculated based upon the assertion level of parity indicator 733. In particular, Modified Soft Input is calculated in accordance with the following pseudocode:

```
If (Parity Indicator 733 Indicates User Data) /* Standard Calculation */
{
  Modified Soft Input =
    Scalar 2 * De-Interleaved Output 797* Input Label at the Branch
}
Else If (Parity Indicator 733 Indicates Parity Data) /* Non-Standard
Calculation */
{
  Modified Soft Input =
    Scalar 2 * De-Interleaved Output 797* Generalized Precoded Input
    Label at the Branch
}
```

Scalar 2 is a user programmable value, and generalized Precoded Input Label at the Branch is accessed from a generalized precoder look up table 736 based upon the standard Input Label at the Branch. The input label of the branch or edge of the trellis node where the state begins.

The result of the computation of branch metric soft input aggregation circuit 738 is a detected output that is provided as soft NRZi output 798. The detected output is also provided to a reverse generalized precode circuit 732 that reverses the generalized precoding applied during a preceding encoding process to the parity data from which the parity data portion of equalized output 725 is derived. Reverse generalized precode circuit 732 uses generalized precoder look up table 736 to look up values corresponding to the detected output corresponding to the parity data portion, and leaves the user data portion unmodified. The resulting output is provided as soft NRZ output 796. Of note, if two different generalized precodings are applied to the user data and parity data, respectively, as discussed above in relation to FIG. 4, then a corresponding two different reverse generalized precodings are applied to the user bits and parity bits, respectively, by data detection circuit 730.

Returning to FIG. 7a, media defect detector circuit 722 may be any circuit known in the art that is capable of identifying media defects based upon a detector output, and soft data based timing loop circuit 724 may be any circuit known in the art that is capable of adjusting the timing of operations used to process data in data processing circuit 700 based upon a detector output. Based upon the disclosure provided herein, one of ordinary skill in the art will recognize a variety of media defect detector circuits and/or soft data based timing loop circuits that may be used in relation to different embodiments of the present invention. Local interleaver circuit 742 is operable to shuffle portions of soft NRZ output 796 to limit the impact of burst errors. Local interleaver circuit 742 may be any circuit known in the art that is capable of shuffling data sets to yield a re-arranged data set. Based upon the disclosure provided herein, one of ordinary skill in the art will recognize a variety of interleaving or shuffling approaches that may be used in relation to different embodiments of the present invention. Local interleaver circuit 742 shuffles sub-portions (i.e., local chunks) of soft NRZ output 796 to yield an interleaved codeword 746 that is stored to central memory circuit 750.

Once a data decoder circuit 775 is available, a previously stored interleaved codeword 746 is accessed from central memory circuit 750 as a decoder input 752 via a global interleaver/de-interleaver circuit 784. In particular, global interleaver/de-interleaver circuit 784 performs a global data shuffling on a data set 786 retrieved from central memory circuit 750 to yield decoder input 752. Data decoder circuit 775 applies a data decode algorithm to decoder input 752 to yield a decoded output. In some embodiments of the present invention, the data decode algorithm is a low density parity check algorithm as are known in the art. Based upon the disclosure provided herein, one of ordinary skill in the art will recognize other decode algorithms that may be used in relation to different embodiments of the present invention. As the data decode algorithm completes on a given data set, it is determined whether the decoded output converged (i.e., the resulting data set matches the originally written data set as indicated by the lack of parity errors). Where it is determined that the decoded output converged, the resulting decoded data set is provided as a hard decision output 772 to a de-interleaver circuit 780. De-interleaver circuit 780 rearranges the data to reverse both the global and local interleaving applied to the data to yield a de-interleaved output 782. De-interleaved output 782 is provided to a maximum transition run length decoder circuit 784 operable to reverse the maximum transition run length encoding originally applied to the source of analog input 705 (e.g., reversing the encoding applied by maximum transmission run length encoder circuit 110). Maximum transition run length decoder circuit 784 provides a decoded output 787. In some cases, maximum transmission run length decoder circuit 784 operates in accordance with Cideciyan, Roy D. et al., “Maximum Transition Run Codes for Generalized Partial Response Channels”, IEEE Journal in Selected Areas in Communications, Vol. 19, No. 4, April 2001. The entirety of the aforementioned article is incorporated herein by reference for all purposes. Decoded output 787 is provided to a hard decision output circuit 790. Hard decision output circuit 790 is operable to re-order data sets that may complete out of order back into their original order. The originally ordered data sets are then provided as a hard decision output 792.

Alternatively, where it is determined that the data decode algorithm failed to converge (i.e., there are remaining parity errors), a completed data set 754 is globally de-interleaved by global interleaver/de-interleaver circuit 784 which essentially reverses the earlier applied global interleaving (i.e., shuffling) to yield a de-interleaved output 788. De-interleaved output 788 is stored to central memory circuit 750.

Once data detector circuit 730 is available, a previously stored decoder output 748 is accessed from central memory circuit 750 and locally de-interleaved by a local de-interleaver circuit 744. Local de-interleaver circuit 744 re-arranges decoder output 748 to reverse the shuffling originally performed by local interleaver circuit 742. A resulting de-interleaved output 797 is provided to data detector circuit 730 where it is used to guide the later application of a data detection algorithm to equalized output 725.

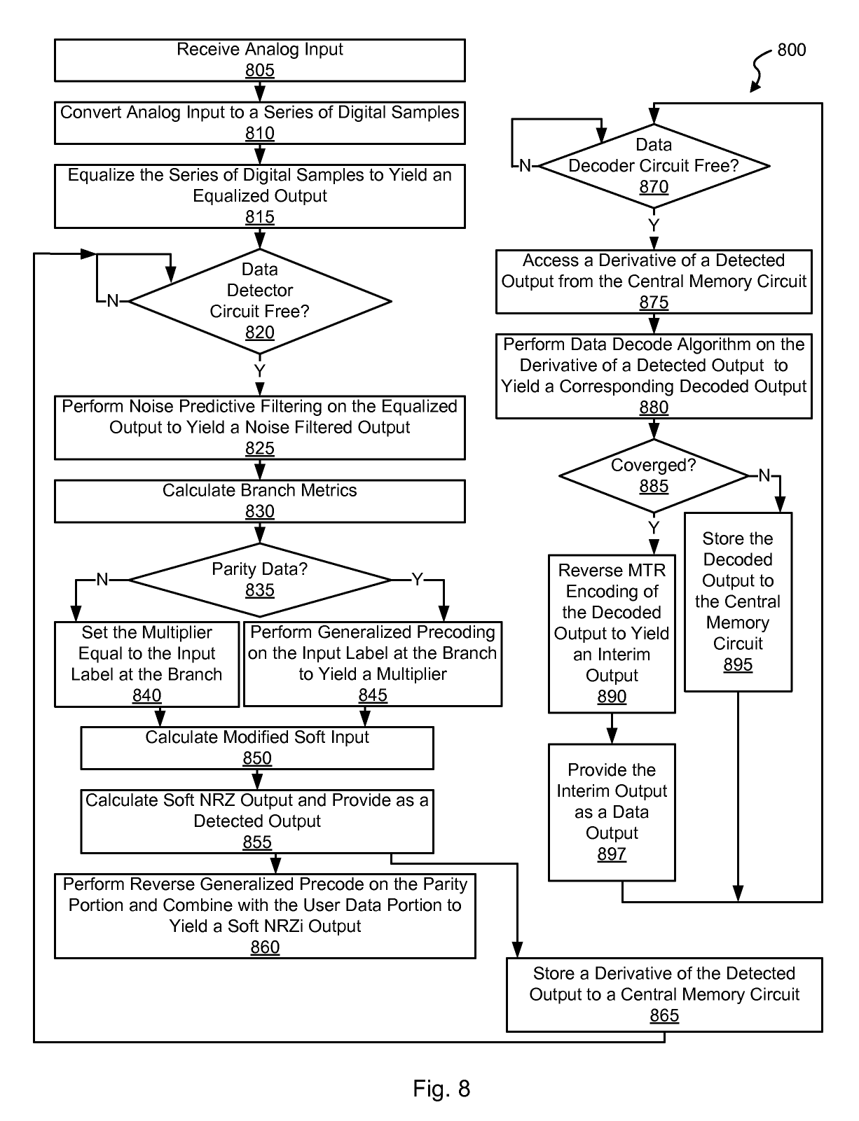

Turning to FIG. 8, a flow diagram 800 shows a method in accordance with some embodiments of the present invention for data detection that includes a reverse generalized precoding in accordance with some embodiments of the present invention. Following flow diagram 800, an analog input signal is received (block 805). The analog input may be derived from, for example, a storage medium or a data transmission channel. Based upon the disclosure provided herein, one of ordinary skill in the art will recognize a variety of sources of the analog input. The analog input is converted to a series of digital samples (block 810). This conversion may be done using an analog to digital converter circuit or system as are known in the art. Of note, any circuit known in the art that is capable of converting an analog signal into a series of digital values representing the received analog signal may be used. The resulting digital samples are equalized to yield an equalized output (block 815). In some embodiments of the present invention, the equalization is done using a digital finite impulse response circuit as are known in the art. Based upon the disclosure provided herein, one of ordinary skill in the art will recognize a variety of equalizer circuits that may be used in place of such a digital finite impulse response circuit to perform equalization in accordance with different embodiments of the present invention. As an example, the equalized output may be similar to the data set shown in FIG. 2d including a run length limited output and precoded parity information.

It is determined whether a data detector circuit is available (block 820). Where a data detector circuit is available (block 820), a noise predictive filtering is applied to the equalized output to yield a noise filtered output (block 825). Branch metrics are then calculated for the respective noise filtered outputs (block 830). The branch metrics may be calculated in accordance with the following equation:

Branch Metric=(y−y_{ideal})²,

where y is the received input, and y_{ideal} is an expected value of the received input.

It is then determined whether the bits being received correspond to the precoded parity information associated with the equalized output (block 840). Where the bits being received correspond to the precoded parity information (block 840), a generalized precoding of the input label at the particular branch is done to yield a multiplier (block 850). Otherwise, the value of the multiplier is set equal to the input label at the particular branch (block 845). A modified soft output is then calculated (block 855). The modified soft output may be calculated in accordance with the following pseudocode:

Modified Soft Input=Scalar 2 * De-Interleaved Output*Multiplier,

where Scalar 2 is a user programmable value, and De-Interleaved Output is derived from a previous application of a data decode algorithm (block 880). A soft NRZ output is calculated and provided as a detected output (block 860). The soft NRZ output may be calculated in accordance with the following equation:

Soft NRZ Output=[Branch Metric/Scalar 1]+Modified Soft Input,

where Scalar 1 is a user programmable value, Branch Metric is that calculated in block 830, and Modified Soft Input is that calculated in block 855. A derivative of the soft NRZ output is stored to a central memory circuit (block 865). In some cases, the derivative of the soft NRZ output is a locally interleaved version of the soft data output. In addition, a reverse generalized precode is performed on the parity portion of the data and the result combined with the user data portion to yield a soft NRZi output (block 860).

In parallel to the previously discussed processing, it is determined whether a data decoder circuit is available (block 870). Where the data decoder circuit is available (block 870) a previously stored derivative of the detected output is accessed from the central memory (block 875). A decode algorithm is applied to the accessed derivative of the detected output to yield a corresponding decoded output (block 880). In some embodiments of the present invention, the data decode algorithm is a low density parity check algorithm as are known in the art. Based upon the disclosure provided herein, one of ordinary skill in the art will recognize other decode algorithms that may be used in relation to different embodiments of the present invention. It is determined whether the decode algorithm converged (i.e., the original data set is identified) (block 885). Where the data decode algorithm converged (block 885), maximum transition run decoding is applied to the decoded output to reverse previously applied maximum transition run encoding yielding an interim output (block 890). The interim output is then manipulated and provided as a data output (block 897). Otherwise, where the data decode algorithm failed to converge (block 885), the decoded output (or a derivative of the decoded output such as, for example, a globally de-interleaved version of the decoded output) is stored back to the central memory circuit for a subsequent global iteration (i.e., processing through both the data detection algorithm and the data decode algorithm) (block 895).

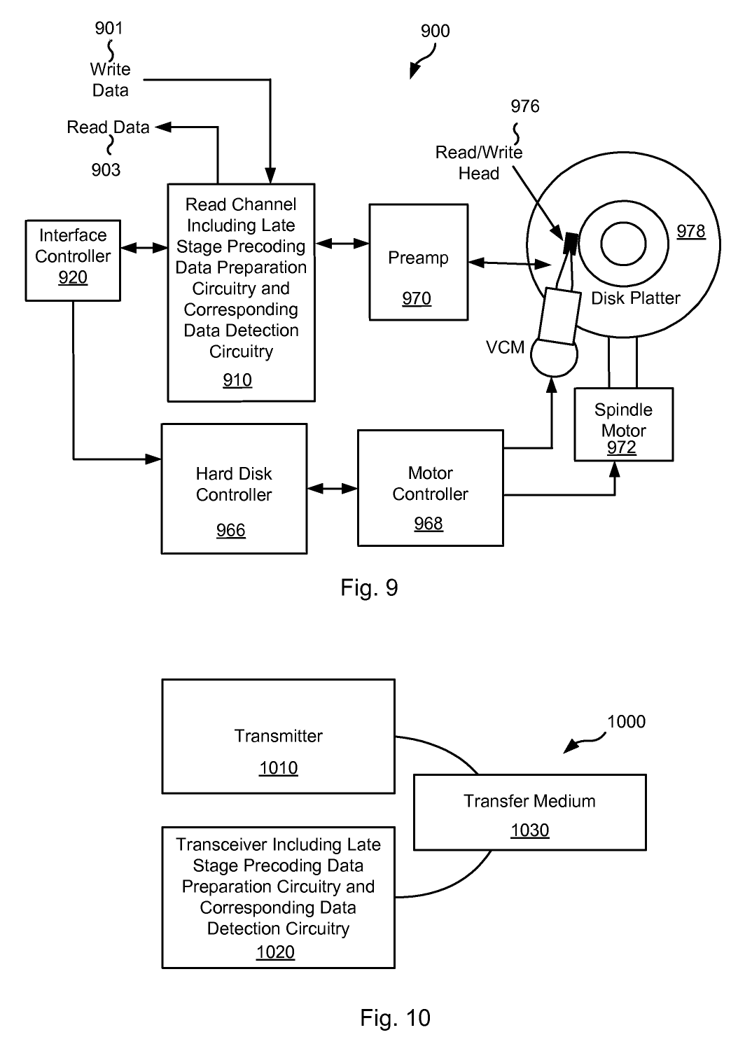

Turning to FIG. 9, a storage device 900 including late stage precoding data preparation circuitry and corresponding data detection circuitry is shown in accordance with one or more embodiments of the present invention. Storage system 900 may be, for example, a hard disk drive. Storage system 900 also includes a preamplifier 970, an interface controller 920, a hard disk controller 966, a motor controller 968, a spindle motor 972, a disk platter 978, and a read/write head assembly 976. Interface controller 920 controls addressing and timing of data to/from disk platter 978. The data on disk platter 978 consists of groups of magnetic signals that may be detected by read/write head assembly 976 when the assembly is properly positioned over disk platter 978. In one embodiment, disk platter 978 includes magnetic signals recorded in accordance with either a longitudinal or a perpendicular recording scheme.

In a typical read operation, read/write head assembly 976 is accurately positioned by motor controller 968 over a desired data track on disk platter 978. Motor controller 968 both positions read/write head assembly 976 in relation to disk platter 978 and drives spindle motor 972 by moving read/write head assembly to the proper data track on disk platter 978 under the direction of hard disk controller 966. Spindle motor 972 spins disk platter 978 at a determined spin rate (RPMs). Once read/write head assembly 978 is positioned adjacent the proper data track, magnetic signals representing data on disk platter 978 are sensed by read/write head assembly 976 as disk platter 978 is rotated by spindle motor 972. The sensed magnetic signals are provided as a continuous, minute analog signal representative of the magnetic data on disk platter 978. This minute analog signal is transferred from read/write head assembly 976 to read channel circuit 910 via preamplifier 970. Preamplifier 970 is operable to amplify the minute analog signals accessed from disk platter 978. In turn, read channel circuit 910 decodes and digitizes the received analog signal to recreate the information originally written to disk platter 978. This data is provided as read data 903 to a receiving circuit. A write operation is substantially the opposite of the preceding read operation with write data 901 being provided to read channel circuit 910. This data is then encoded and written to disk platter 978.

During operation, the late stage precoding data preparation circuitry and corresponding data detection circuitry is operable to encode data prior to writing the data to disk platter 978. The encoded information may be encoded using an encoding circuit similar to that discussed above in relation to FIG. 1 or FIG. 4, and or may be encoded using a method similar to that discussed above in relation to FIG. 3 or FIG. 6. When the encoded data is later retrieved from disk platter 978, a data detection and decoding circuit decodes the data to recover the originally written data. A decoding circuit similar to that discussed above in relation to FIG. 7 may be used, and/or the decoding process may be done using a method similar to that discussed above in relation to FIG. 8

It should be noted that storage system may utilize SATA, SAS or other storage technologies known in the art. Also, it should be noted that storage system 900 may be integrated into a larger storage system such as, for example, a RAID (redundant array of inexpensive disks or redundant array of independent disks) based storage system. It should also be noted that various functions or blocks of storage system 900 may be implemented in either software or firmware, while other functions or blocks are implemented in hardware.

Turning to FIG. 10, a communication system 1000 including a transceiver 1020 having late stage precoding data preparation circuitry and corresponding data detection circuitry in accordance with one or more embodiments of the present invention. Communication system 1000 includes a transmitter 1010 that is operable to transmit encoded information via a transfer medium 1030 as is known in the art. The encoded information may be encoded using an encoding circuit similar to that discussed above in relation to FIG. 1 or FIG. 4, and or may be encoded using a method similar to that discussed above in relation to FIG. 3 or FIG. 6. The encoded data is received from transfer medium 1030 by transceiver 1020.

Transceiver 1020 incorporates late stage precoding data preparation circuitry and corresponding data detection circuitry. While processing received data, received data is converted from an analog signal to a series of corresponding digital samples, and the digital samples are equalized to yield an equalized output. The equalized output is then provided to a data processing circuit including both a data detector circuit and a data decoder circuit. Data is passed between the data decoder and data detector circuit via a central memory allowing for variation between the number of processing iterations that are applied to different data sets. It should be noted that transfer medium 1030 may be any transfer medium known in the art including, but not limited to, a wireless medium, an optical medium, or a wired medium. Based upon the disclosure provided herein, one of ordinary skill in the art will recognize a variety of transfer mediums that may be used in relation to different embodiments of the present invention.

During operation, the late stage precoding data preparation circuitry and corresponding data detection circuitry may encode data for transmission using an encoding circuit similar to that discussed above in relation to FIG. 1 or FIG. 4, and or may be encoded using a method similar to that discussed above in relation to FIG. 3 or FIG. 6. The encoded data is received from transfer medium 1030 by transceiver 1020. In addition, the circuitry may decode received data sets using a decoding circuit similar to that discussed above in relation to FIG. 7, and/or may decode the received data set using a method similar to that discussed above in relation to FIG. 8.

It should be noted that the various blocks discussed in the above application may be implemented in integrated circuits along with other functionality. Such integrated circuits may include all of the functions of a given block, system or circuit, or only a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data processing device, wherein the data processing device comprises:
a data encoding system operable to receive a data input, and to:
apply a maximum transition run length encoding to the data input to yield a run length limited output;
apply a low density parity check encoding algorithm to the run length limited output to yield a number of original parity bits;
apply a precode algorithm to the original parity bits to yield precoded parity bits; and
combine the precoded parity bits and a derivative of the run length limited output to yield an output data set; and
a data decoding system operable to receive the output data set, and to:
perform a data detection on the output data set to yield a detected output; and
apply a low density parity check decode algorithm to a derivative of the detected output to yield a decoded output.

2. The data processing device of claim 1, wherein performing the data detection comprises:
applying a data detection algorithm that is selected from a group consisting of: a maximum a posteriori data detection algorithm, and a Viterbi data detection algorithm.

3. The data processing device of claim 1, wherein the derivative of the run length limited output is the run length limited output, and wherein performing the data detection comprises:
applying a precode decoding algorithm to at least the precoded parity bits to yield the original parity bits; and
applying a data detection algorithm to a combination of the original parity bits and the run length limited output to yield the detected output.

4. The data processing device of claim 1, wherein the precode algorithm is a first precode algorithm, and wherein the data encoding system is further operable to apply a second precode algorithm to the run length limited output to yield the derivative of the run length limited output; and wherein performing the data detection comprises:
applying a combination data detection algorithm and precode decoding algorithm to the output data set to yield the detected output.

5. The data processing device of claim 1, wherein the data encoding system is implemented as part of a first integrated circuit, and wherein the data decoding system is implemented as part of a second integrated circuit.

6. The data processing device of claim 1, wherein the data encoding system and the data decoding system are implemented as part of an integrated circuit.

7. The data processing device of claim 1, wherein the data processing device is selected from a group consisting of: a storage device, a wired communication device, and a wireless communication device.

8. A data processing system, the data processing system comprising:
a data encoding system operable to receive a data input, and to:
apply a maximum transition run length encoding to the data input to yield a run length limited output;
apply an encoding algorithm to the run length limited output to yield a number of original parity bits;
apply a precode algorithm to the original parity bits to yield precoded parity bits; and
combine the precoded parity bits and a derivative of the run length limited output to yield an output data set.

9. The data processing system of claim 8, wherein the derivative of the run length limited output is the run length limited output.

10. The data processing system of claim 8, wherein the precode algorithm is a first precode algorithm, and wherein the data encoding system is further operable to apply a second precode algorithm to the run length limited output to yield the derivative of the run length limited output.

11. The data processing system of claim 8, wherein applying the precode algorithm to the original parity bits to yield the precoded parity bits includes replacing portions of the original parity bits with replacement parity bits.

12. The data processing system of claim 11, wherein the data processing system further comprises:
a look up table operable to store the replacement parity bits; and
wherein the look up table is addressed by respective derivatives of the portions of the original parity bits to yield the corresponding replacement parity bits.

13. The data processing system of claim 8, wherein the encoding algorithm is a low density parity check encoding algorithm.

14. The data processing system of claim 8, wherein the data processing system is implemented as part of an integrated circuit.

15. The data processing system of claim 8, wherein the data processing system is implemented as part of a device selected from a group consisting of: a storage device, a wired communication device, and a wireless communication device.

16. A data processing system, the data processing system comprising:
a data decoding system operable to receive an output data set, wherein the output data set includes a combination of a derivative of a run length limited output and precoded parity bits, and wherein the data decoding system is further operable to:
perform a data detection on the output data set to yield a detected output; and
apply a parity check based decode algorithm to the detected output to yield a decoded output.

17. The data processing system of claim 16, wherein the parity check based decode algorithm is a low density parity check decoding algorithm.

18. The data processing system of claim 16, wherein the data processing system is implemented as part of an integrated circuit.

19. The data processing system of claim 16, wherein the data processing system is implemented as part of a device selected from a group consisting of: a storage device, a wired communication device, and a wireless communication device.

20. The data processing system of claim 16, wherein performing the data detection comprises:
applying a data detection algorithm that is selected from a group consisting of: a maximum a posteriori data detection algorithm, and a Viterbi data detection algorithm.

21. The data processing system of claim 16, wherein the derivative of the run length limited output is the run length limited output, and wherein performing the data detection comprises:
applying a precode decoding algorithm to at least the precoded parity bits to yield the original parity bits; and
applying a data detection algorithm to a combination of the original parity bits and the run length limited output to yield the detected output.

22. The data processing system of claim 21, wherein applying the precode decoding algorithm to at least the precoded parity bits to yield the original parity bits includes replacing portions of the precoded parity bits with replacement parity bits.

23. The data processing system of claim 22, wherein the data processing system further comprises:
a look up table operable to store the replacement parity bits; and
wherein the look up table is addressed by respective derivatives of the portions of the precoded parity bits to yield the corresponding replacement parity bits.

24. The data processing system of claim 16, wherein the derivative of the run length limited output is a precoded version of the run length limited output, and wherein the performing the data detection comprises:
applying a combination data detection algorithm and precode decoding algorithm to the output data set to yield the detected output.
